(19) United States
(12) Patent Application Publication
(10) Pub. No.: US 2011/0090661 A1
(43) Pub. Date: Apr. 21, 2011

(54) CIRCUIT BOARD WITH CAPACITOR HAVING A MULTILAYER BODY AND DISPLAY DEVICE USING SAME

(75) Inventors: XU HONG, Shenzhen (CN); ZHAN-WEI FU, Shenzhen (CN); MING-FENG YU, Miao-Li (TW)

(73) Assignees: INNOCOM TECHNOLOGY (SHENZHEN) CO., LTD., Shenzhen City (CN); INNOLUX DISPLAY CORP., Miao-Li County (TW)

(21) Appl. No.: 12/713,324

(22) Filed: Feb. 26, 2010

(30) Foreign Application Priority Data
Oct. 19, 2009 (CN) 200910308454.4

(51) Int. Cl. H05K 7/00

(52) U.S. Cl. 361/782; 361/679.01; 361/321.2

(57) ABSTRACT

An exemplary circuit board includes a plate body and a multilayer capacitor installed on a surface of the plate body. The multilayer capacitor includes a multilayer body and two outer electrodes located at the two opposite ends of the multilayer body. The multilayer body includes a plurality of ceramic layers and a plurality of internal electrodes alternately arranged. The two outer electrodes are connected to the plate body, and a stacking direction of the multilayer body is substantially parallel to the surface of the plate body.

### BACKGROUND

1. Technical Field

The present disclosure generally relates to electronic devices, and particularly to a circuit board and a display device using the circuit board.

2. Description of Related Art

Circuit boards are basic components of numerous electronic devices. A conventional circuit board includes a main board and a plurality of electronic components installed on the main board. The electronic components may include chips, resistors, capacitors and the like. Multilayer ceramic capacitors offer small volume, high voltage capacity, high temperature resistance, good mass-production capability, and other advantages. Thus, multilayer ceramic capacitors are widely used in high frequency electronics and portable devices, particularly those utilizing a display.

However, when the above-described kind of circuit board is working, external alternating current (AC) signals in the frequency range of from 20 Hz (hertz) to 20 kHz (kilohertz) may enter the multilayer ceramic capacitors. When this happens, the multilayer ceramic capacitors produce vibration in directions vertical to the main board of the circuit board, generating audible noise. The quality of the circuit board may deteriorate, and the enjoyment of the portable device may be diminished.

What are called for, accordingly, are a circuit board and a display device using the circuit board which can overcome the described limitations.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the several views, and all the views are schematic.

FIG. 1 is an exploded, isometric view of part of a preferred embodiment of a circuit board of the present disclosure.

FIG. 2 is an isometric view of the circuit board of FIG. 1 rotated 180° from top to bottom.

FIG. 3 is an assembled, side plan view of the circuit board of FIG. 1.

FIG. 4 is an exploded, side view of a display device utilizing the circuit board of FIG. 1.

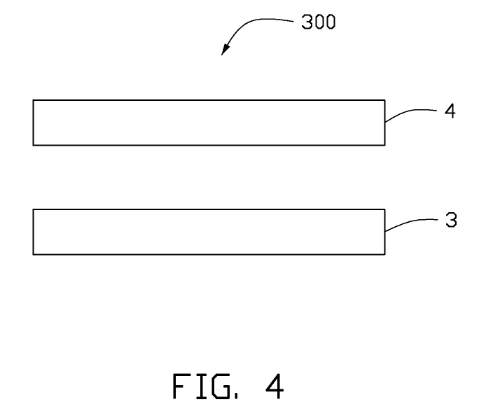

### DETAILED DESCRIPTION

Reference will now be made to the drawings to describe embodiments in detail.

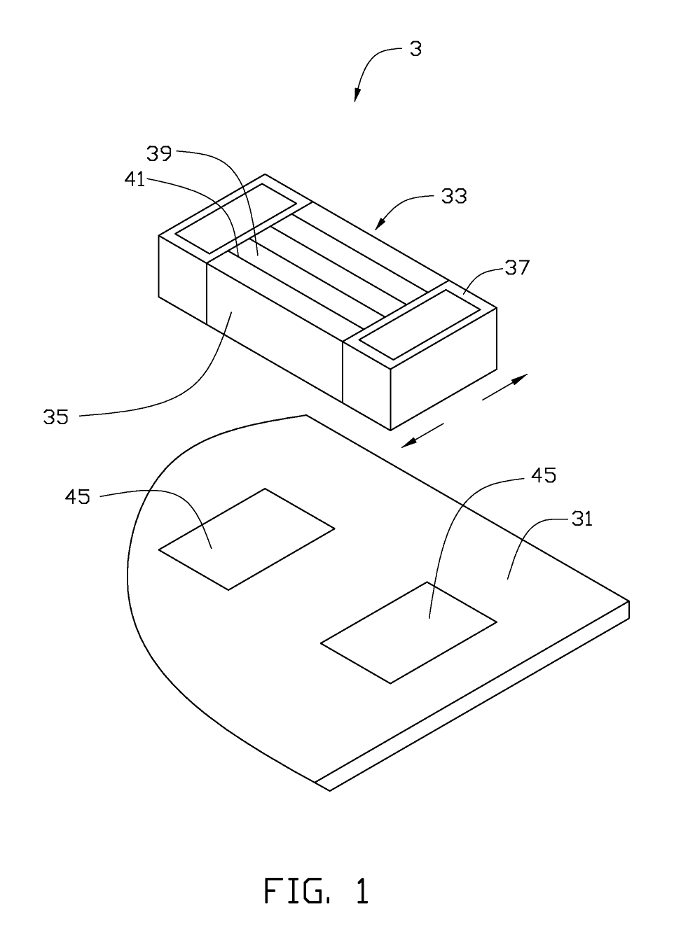

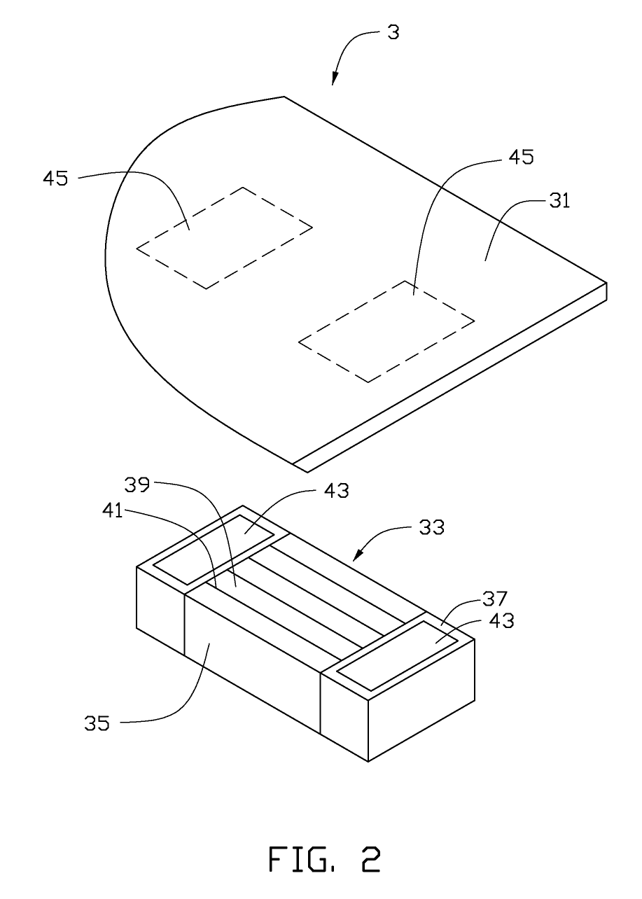

Referring to FIGS. 1-3, a circuit board 3 includes a plate body 31 and a capacitor 33 installed over a surface of the plate body 31.

The capacitor 33 is a commonly used multilayer ceramic capacitor, including a multilayer body 35 and two outer electrodes 37 located at two opposite ends thereof. The multilayer body 35 includes a plurality of ceramic layers 39 and a plurality of internal electrodes 41. The internal electrodes 41 are in the form of layers. The ceramic layers 39 and the internal electrodes 41 are alternately stacked along a horizontal direction, as shown in FIG. 1, with the stack lying parallel to the surface of the plate body 31. The internal electrodes 41 and the ceramic layers 39 are rectangular and laminated together, with the internal electrodes 41 parallel to the ceramic layers 39. The outer electrodes 37 connect with all the internal electrodes 41 electrically. Every two adjacent internal electrodes 41 and a ceramic layer 39 therebetween cooperatively form a plate capacitor. All the plate capacitors are connected in parallel by the electrical connections of the internal electrodes 41 and the outer electrodes 37. Accordingly, a capacity of the capacitor 33 can be increased. The outer electrodes 37 each include a weld 43 connected with the circuit board 3. The weld 43 is located on a bottom surface of each outer electrode 37, and the bottom surface of the outer electrode 37 is parallel to a bottom surface of the multilayer body 35. In the illustrated embodiment, the bottom surfaces of the outer electrodes 37 are coplanar with the bottom surface of the multilayer body 35.

Two flat metal contacts 45 are disposed on a top surface of the plate body 31. The surfaces of the metal contacts 45 are each coated with a layer of tin (solder) paste 47. One weld 43 connects with one of the two metal contacts 45 via the solder paste 47, and the other weld 43 connects with the other metal contact 45 via the solder paste 47, by surface mounting technology (SMT). There is a very small gap 49 between the multilayer body 35 and the plate body 31. In alternative embodiments, the solder paste 47 can be omitted.

When external AC signals, such as pulse width modulation (PWM) signals, reach the capacitor 33, since the stacking direction of the multilayer body 35 is parallel to the surfaces of the metal contacts 45 on the plate body 31, the ceramic layers 39 of the multilayer body 35 are apt to produce vibration in directions parallel to the plate body 31, as shown in FIG. 1. Force of the vibration of the multilayer body 35 is transmitted along directions parallel with the top surface of the plate body 31. In addition, there is the gap 49 between the multilayer body 35 and the plate body 31. Therefore, mechanical interrelation between the plate body 31 and the capacitor 33 is minimal, and little or even no audible noise is generated.

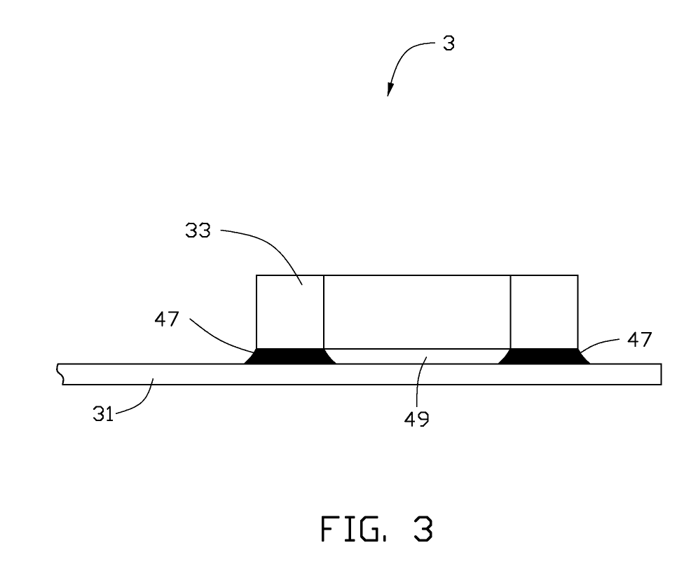

Referring to FIG. 3, a display device 300 includes a display panel 4 and the circuit board 3. The display panel 4 connects with the circuit board 3 electrically. The display panel 4 is used to display images. The circuit board 3 is used to provide signals for the display panel 4. The quality of the display device 300 is improved because the quality of the circuit board 3 is improved.

The display device 300 can be a liquid crystal display (LCD) device, a light-emitting diode (LED) device, an electroluminescent device, and the like. Other electronic devices such as mobile phones, notebook computers, etc can also advantageously employ the circuit board 3.

It is believed that the present embodiments and their advantages will be understood from the foregoing description, and it will be apparent that various changes may be made thereto without departing from the spirit and scope of the embodiments or sacrificing all of their material advantages.

What is claimed is:

1. A circuit board, comprising:
a plate body comprising a surface; and
a multilayer capacitor installed over the surface of the plate body, the multilayer capacitor comprising a multilayer body and two outer electrodes located at two opposite ends of the multilayer body, wherein the two outer electrodes are connected to the plate body, and a stacking direction of the multilayer body is substantially parallel to the surface of the plate body.

2. The circuit board of claim 1, wherein the multilayer body comprises a plurality of ceramic layers and a plurality of internal electrodes alternately arranged.

3. The circuit board of claim 2, wherein the internal electrodes connect with the two outer electrodes, with every two adjacent internal electrodes and a ceramic layer therebetween cooperatively forming a plate capacitor.

4. The circuit board of claim 3, wherein the plate body comprises two metal contacts, each outer electrode comprises a weld, and the outer electrodes and the plate body are connected by the metal contacts connecting with the welds, respectively.

5. The circuit board of claim 4, wherein the welds are located on bottom surfaces of the outer electrodes, respectively, and the bottom surfaces of the outer electrodes are substantially parallel to the surface of the plate body.

6. The circuit board of claim 5, wherein each of the outer electrodes is connected with the corresponding metal contact by a layer of solder paste, and a gap is defined between the multilayer body of the multilayer capacitor and the plate body.

7. A circuit board, comprising:
a plate body comprising a surface; and
a multilayer capacitor installed over the surface of the plate body, the multilayer capacitor comprising a multilayer body and two outer electrodes located at two opposite ends of the multilayer body, wherein the two outer electrodes are connected with the plate body, and the multilayer body is oriented such that under a condition that the multilayer body vibrates during operation of the circuit board, vibration directions of the multilayer body are substantially parallel to the surface of the plate body.

8. The circuit board of claim 7, wherein the plate body comprises two metal contacts, each outer electrode comprises a weld, and the outer electrodes and the plate body are connected by the metal contacts connecting with the welds, respectively.

9. The circuit board of claim 8, wherein the welds are located on bottom surfaces of the outer electrodes, respectively, and the bottom surfaces of the outer electrodes are parallel to the surface of the plate body.

10. The circuit board of claim 9, wherein each of the outer electrodes is connected with the corresponding metal contact by a layer of solder paste, and a gap is defined between the multilayer body of the multilayer capacitor and the plate body.

11. The circuit board of claim 10, wherein the multilayer body comprises a plurality of ceramic layers and a plurality of internal electrodes alternately arranged.

12. The circuit board of claim 11, wherein the internal electrodes connect with the two outer electrodes, with every two adjacent internal electrodes and a ceramic layer therebetween cooperatively forming a plate capacitor.

13. A display device, comprising:
a display panel; and
a circuit board connecting with the display panel, the circuit board comprising:
a plate body comprising a surface; and
a multilayer capacitor installed on the surface of the plate body, the capacitor comprising a multilayer body and two outer electrodes located at two opposite ends of the multilayer body, wherein the two outer electrodes are connected to the plate body, and a stacking direction of the multilayer body is substantially parallel to the surface of the plate body.

14. The display device of claim 13, wherein the multilayer body comprises a plurality of ceramic layers and a plurality of internal electrodes alternately arranged.

15. The display device of claim 14, wherein the internal electrodes connect with the two outer electrodes, with every two adjacent internal electrodes and a ceramic layer therebetween cooperatively forming a plate capacitor.

16. The display device of claim 15, wherein the plate body comprises two metal contacts, each outer electrode comprises a weld, and the outer electrodes and the plate body are connected by the metal contacts connecting with the welds, respectively.

17. The display device of claim 16, wherein the welds are located on bottom surfaces of the outer electrodes, respectively, and the bottom surfaces of the outer electrodes are parallel to the surface of the plate body.

18. The display device of claim 17, wherein each of the outer electrodes is connected with the corresponding metal contact by a layer of solder paste, and a gap is defined between the multilayer body of the multilayer capacitor and the plate body.

19. The display device of claim 13, wherein the display device is one of a liquid crystal display device, a light-emitting diode device, and an electroluminescent device.
